(19) United States
(12) Patent Application Publication
(10) Pub. No.: US 2008/0204078 A1
(43) Pub. Date: Aug. 28, 2008

(54) LEVEL SHIFTER FOR PREVENTING STATIC CURRENT AND PERFORMING HIGH-SPEED LEVEL SHIFTING

(75) Inventor: Se Eun O, Gyeonggi-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/938,520

(22) Filed: Nov. 12, 2007

(30) Foreign Application Priority Data
Feb. 27, 2007 (KR) 2007-0019702

(51) Int. Cl. H03K 19/0185

(52) U.S. Cl. 326/81

(57) ABSTRACT

A level shifter amplifies a voltage of a digital signal to a predetermined voltage and outputs the amplified signal. The level shifter is capable of preventing generation of static current, and performing high-speed level shifting by increasing the speed of charging electric charges into or discharging electric charges from an output terminal of a differential amplification circuit included in the level shifter.

### CROSS-REFERENCE TO RELATED PATENT APPLICATIONS

This application claims the benefit of Korean Patent Application No. 10-2007-0019702, filed on Feb. 27, 2007, in the Korean Intellectual Property Office, the disclosure of which is incorporated herein in its entirety by reference.

### BACKGROUND OF THE INVENTION

1. Field of the Invention

The present invention relates to a level shifter, and more particularly, to a level shifter capable of performing high-speed level shifting and preventing generation of static current.

2. Description of the Related Art

Level shifters have been used extensively in various types of digital circuits in order to increase the voltage of a signal to a predetermined voltage. Important characteristics of level shifter include speed of level shifting, static current, driving voltage, and so on. Static current refers to current that flows via a DC current path through the level shifter that is formed when amplifying an applied voltage, i.e., by performing level shifting.

FIG. 1 is a circuit diagram of a level shifter 100 according to the related art. Referring to FIG. 1, the level shifter 100 includes an input circuit 110, a differential amplification circuit 120, and an output circuit 130.

The input circuit 110 improves the current driving capability of an input signal IN by using a pair of inverters, and outputs differential input signals IN1 and IN2. The differential amplification circuit 120 amplifies the differential input signals IN1 and IN2 so as to shift the voltages of the input signals IN1 and IN2.

The output circuit 130 includes a pair of inverters that are connected in series between one of a plurality of output terminals of the differential amplification circuit 120 and an output terminal OUT of the level shifter 100.

The differential amplification circuit 120 includes a pair of transistors P2 and P3 in order to alleviate current contention between a first input transistor N0 and a first load transistor P0 and between a second input transistor N1 and a second load transistor P1. In general, current contention occurs during the switching operations of a plurality of transistors. That is, current contention refers to contention between a transistor that is turned on or off in order to allow electric charges to be charged to or discharged from a node, and another transistor that prevents electric charges from being charged into or discharged from the node when the former transistor is turned on or off.

The pair of the transistors P2 and P3 lower the driving voltage of differential amplification circuit 120, but also affect the driving capabilities of the load transistors P0 and P1. Accordingly, the level shifter 100 cannot perform high-speed level shifting.

FIG. 2 is a circuit diagram of another level shifter 200 according to the related art. Referring to FIG. 2, the level shifter 200 includes load transistors P0 and P1 having a current mirror structure, thus preventing current contention between a pair of differential transistors N0 and N1 and the load transistors P0 and P1. Accordingly, the level shifter 200 is capable of performing high-speed level shifting.

The level shifter 200 includes a plurality of transistors P2 and P3 which are intended to prevent generation of static current. However, static current is actually generated since a current path is formed between the load transistor P0 and a first input transistor N0 of the pair of differential transistors N0 and N1.

FIG. 3 is a circuit diagram of another level shifter 300 according to the related art. Referring to FIG. 3, the level shifter 300 also includes load transistors P0 and P1 having a current mirror structure. Thus, current contention does not occur between a pair of differential transistors N0 and N1 and the load transistors P0 and P1.

The level shifter 300 further includes a transistor P3 connected between the gates of the load transistors P0 and P1 and a supply voltage VDD2 in order to prevent generation of static current.

Although static current is not generated in the level shifter 300, the transistor P3 increases the load on the differential transistors N0 and N1, thereby degrading the high-speed level shifting performance of the level shifter 300.

As increasingly thinner and smaller digital circuits have been developed to can operate at high speeds and with low voltage supplies, there is an increasing demand for a level shifter that can perform high-speed level shifting, prevent generation of static current, and operate with low voltage supplies.

### SUMMARY OF THE INVENTION

The present invention provides a level shifter capable of performing high-speed level shifting and preventing generation of static current, even at low input voltage.

According to an aspect of the present invention, there is provided a level shifter that can prevent generation of static current, and perform high-speed level shifting by increasing the speed of charging or discharging an output terminal of a differential amplification circuit included in the level shifter.

The level shifter includes a pair of differential transistors, a first transistor, a second transistor, and a third transistor. The differential transistors include a first input terminal and a second input terminal, and are first conductive type transistors.

The first transistor is a first conductive type transistor that is connected between a first node and a first output terminal of the differential transistors and has a gate connected to a second node. The second transistor is a second conductive type transistor connected between a supply voltage and the first node.

The third transistor is a second conductive type transistor which is connected between the supply voltage and a second output terminal of the differential transistors and has a gate connected to the first node.

The level shifter may further include an inverter and a fourth transistor. The inverter is connected between the second output terminal of the differential transistors and the second node. The fourth transistor is a second conductive type transistor that is connected between the supply voltage and the second output terminal of the differential transistors and has a gate connected to the second node.

The second transistor may have a gate connected to the first input terminal or to a ground voltage. The first input transistor and the second input transistor of the differential transistors may have a zero threshold voltage.

A source of the first input transistor may be connected to the second input terminal, and a source of the second input transistor may be connected to the first input terminal.

According to another aspect of the present invention, there is provided a level shifter including a pair of differential transistors, a first transistor, a second transistor, and a third transistor. The differential transistors have a first input terminal and a second input terminal, and are first conductive type transistors.

The first transistor is a second conductive type transistor that is connected between a first node and a first output terminal of the differential transistors and has a gate connected to a second output terminal of the differential transistors.

The second transistor is a second conductive type transistor connected between a supply voltage and the first node. The third transistor is a second conductive type transistor that is connected between the supply voltage and a second output terminal of the differential transistor and has a gate connected to the first node.

The level shifter may further include an inverter and a fourth transistor. The inverter is connected between the second output terminal of the differential transistors and a second node. The fourth transistor is a second conductive type transistor that is connected between the supply voltage and the second output terminal of the differential transistors and has a gate connected to the second node.

The second transistor has a gate connected to the first input terminal or to a ground voltage.

According to another aspect of the present invention, there is provided a level shifter including a pair of differential transistors, a pair of first transistors, a second transistor, a third transistor, and a fourth transistor. The differential transistors include a first input terminal and a second input terminal, and are first conductive type transistors.

The first transistors are first conductive type transistors that are connected in parallel between a first node, a second node, and output terminals of the differential transistors, and have Rates connected to a first supply voltage.

The second transistor is a first conductive type transistor that is connected between a third node and the first node and has a gate connected to a fourth node. The third transistor is a second conductive type transistor that is connected between a second supply voltage and the third node and has a gate connected to the first input terminal.

The fourth transistor is a second conductive type transistor that is connected between the second supply voltage and the second node and has a gate connected to the third node.

The second supply voltage may be obtained by level shifting the first supply voltage. A gate layer of each of the first transistors may have a break-down voltage equal to the second supply voltage, and a zero threshold voltage.

The level shifter may further include an inverter and a fifth transistor. The inverter is connected between the second node and the fourth node. The fifth transistor is a second conductive type transistor that is connected between the second supply voltage and the second node and has a gate connected to the fourth node.

### BRIEF DESCRIPTION OF THE DRAWINGS

The above and other features and advantages of the present invention will become more apparent by describing in detail exemplary embodiments thereof with reference to the attached drawings in which:

FIG. 1 is a circuit diagram of a level shifter according to the related art;

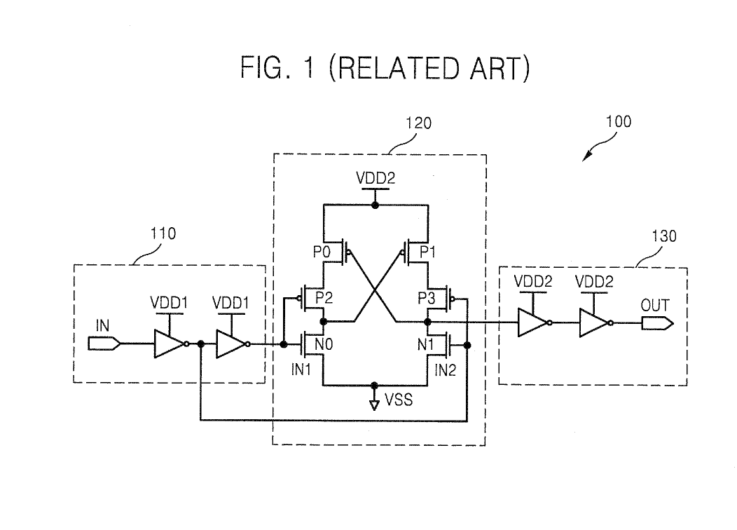

FIG. 2 is a circuit diagram of another level shifter according to the related art;

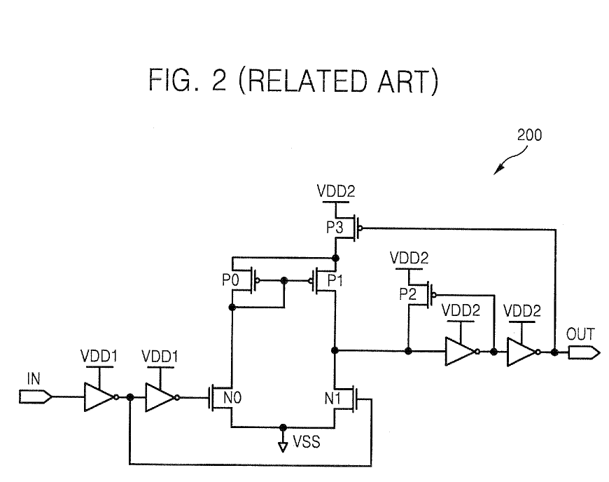

FIG. 3 is a circuit diagram of another level shifter according to the related art;

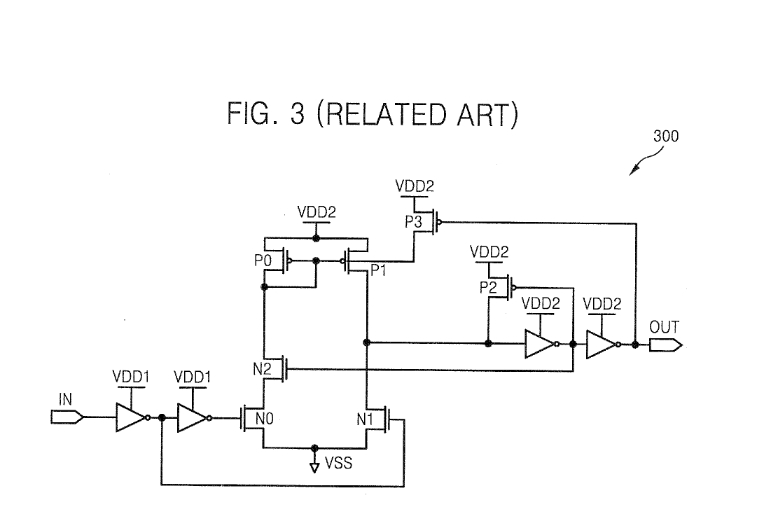

FIG. 4 is a circuit diagram of a level shifter according to an embodiment of the present invention;

FIG. 5 is a circuit diagram of a level shifter according to another embodiment of the present invention;

FIG. 6 is a circuit diagram of a level shifter according to another embodiment of the present invention;

FIG. 7 is a circuit diagram of a level shifter according to another embodiment of the present invention;

FIG. 8 is a circuit diagram of a level shifter according to another embodiment of the present invention; and

FIG. 9 is a circuit diagram of a level shifter according to another embodiment of the present invention.

### DETAILED DESCRIPTION OF THE INVENTION

Exemplary embodiments of the present invention will now be described more fully with reference to the accompanying drawings. Like reference numerals denote like elements throughout the drawings.

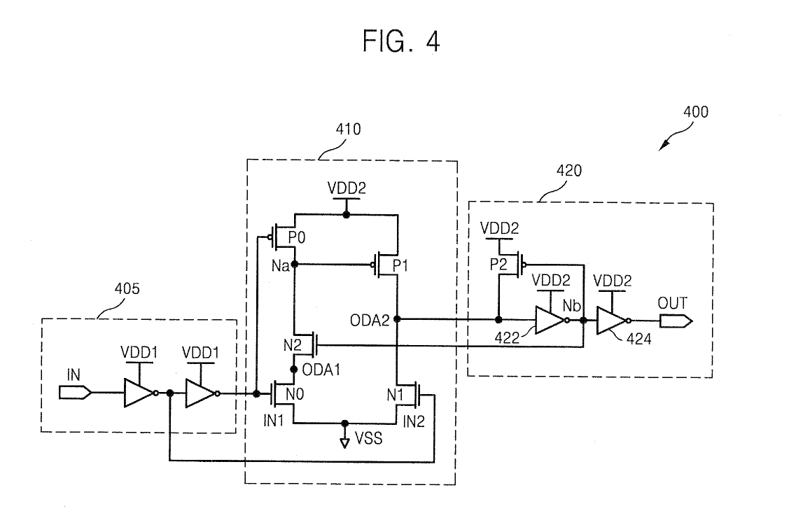

FIG. 4 is a circuit diagram of a level shifter 400 according to an embodiment of the present invention. Referring to FIG. 4, the level shifter 400 includes an input circuit 405, a differential amplification circuit 410, and an output circuit 420.

The level shifter 400 can perform high-speed level shifting by increasing the speed of charging or discharging of a second output terminal ODA2 of the differential amplification circuit 410. The input circuit 405 improves the current driving capability of an input signal IN by using a pair of inverters, and transmits a plurality of differential input signals IN1 and IN2 to the differential amplification circuit 410.

The differential amplification circuit 410 amplifies and outputs the differential input signals. The differential amplification circuit 410 includes a pair of differential transistors N0 and N1, a first transistor N2, a second transistor P0, and a third transistor P1. The differential transistors N0 and N1 include a first input terminal IN1 and a second input terminal IN2. The differential transistors N0 and N1 may be first conductive type transistors.

The first transistor N2 may be a first conductive type transistor that is connected between a first node Na and a first output terminal ODA1 of the differential transistors N0 and N1 (hereinafter referred to as “first output terminal”) and has a gate connected to a second node Nb.

The second transistor P0 may be a second conductive type transistor that is connected between a supply voltage VDD2 and the first node Na and has a gate connected to the first input terminal IN1.

The third transistor P1 may be a second conductive type transistor that is connected between the supply voltage VDD2, and a second output terminal ODA2 of the differential transistors N0 and N1 (hereinafter referred to as “second output terminal”) and has a gate connected to the first node Na.

The output circuit 420 is connected to the second output terminal ODA2 and outputs a level-shifted voltage via a pair of inverters 422 and 424 that are connected in series between the second output terminal ODA2 and an output terminal OUT of the level shifter 400.

The output circuit 420 includes a fourth transistor P2 of the second conductive type that is connected between the supply voltage VDD2 and the second output terminal ODA2. The gate of the fourth transistor P2 is connected to the second node Nb. The fourth transistor P2 is a pull-up transistor and is thus smaller than the differential transistors N0 and N1.

The first conductive transistors may be N-channel metallic oxide semiconductor field effect transistors (MOSFETs), and the second conductive transistors may be P-channel MOSFETs.

A process through which the level shifter 400 prevents generation of static current and performs high-speed level shifting will now be described. For convenience of explanation, the turn-on resistance of each of the transistors of the level shifter 400, and the voltage drop between the source and drain of each of the transistors when they are turned on are not considered.

First, the operation of the level shifter 400 when a first input signal that goes low is supplied to the first input terminal IN1 and a second input signal that goes high is supplied to the second input terminal IN2 will be described.

When the first input signal goes low, the first input transistor N0 is turned off and the second transistor P0 is turned on. If the second transistor P0 is turned on, the first node Na is at logic high and then the third transistor P1 is turned off.

When the second input signal goes high, the second input transistor N1 is turned on and then the second output terminal ODA2 is at logic low. If the second output terminal ODA2 is at logic low, the second node Nb is at logic high.

Since the second node Nb is at logic high, the first transistor N2 is turned on, the first node Na is at logic high, and then, the fourth transistor P2 is turned off. As described above, the first input transistor N0, the third transistor P1, and the fourth transistor P2 are turned off, thus preventing static current from being generated.

Next, the operation of the level shifter 400 when the first input signal transitions from logic low to logic high and the second input signal transitions from logic high to logic low will be described. Whether the level shifter 400 performs high-speed level shifting or not is determined when each of the first and second input signals transitions from logic high to logic low or vice versa. If the first input signal transitions from logic low to logic high, the first input transistor N0 is turned on, the first output terminal ODA1 is at logic low, and then, the second transistor P0 is turned off.

Even if the second input signal transitions from logic high to logic low, the second node Nb is temporarily maintained at logic high, due to a delay in the inverter 422 of the output circuit 420.

Since the second node Nb is temporarily maintained at logic high, the first transistor N2 is turned on and the first node Na is thus at logic low. Since the first node Na is at logic low, the third transistor P1 is turned on and then the second output terminal ODA2 is at logic high.

If the second output terminal ODA2 is at logic high, the second node Nb is at logic low, the fourth transistor P2 is turned on, the second output terminal ODA2 is at logic high, and then the first transistor N2 is turned off.

In order to allow the level shifter 400 to perform high-speed level shifting, electric charges charged to the first node Na via the second transistor P0 must be rapidly discharged to a ground voltage VSS via the first input transistor N0. That is, current contention occurs between the second transistor P0 and the first input transistor N0. The second transistor P0 is a pull-up transistor and thus smaller than the first input transistor N0.

Also, the second transistor P0 is gated together with the first input transistor N0 by the first input signal, and thus, the first input transistor N0 has an advantage over the second transistor P0 in current contention.

Thus, the level shifter 400 can perform high-speed level shifting while the first input signal transitions from logic low to logic high and the second input signal transitions from logic high to logic low.

When the first input signal is maintained at logic high and the second input signal is maintained at logic low, the first transistor N2, the second transistor P0, the third transistor P1, and the second input transistor N1 are turned off, and thus, static current is not generated.

Next, the operation of the level shifter 400 when the first input signal transitions from logic high to logic low and the second input signal transitions from logic low to logic high will be described.

If the first input signal goes low, the first input transistor N0 is turned off, the second transistor P0 is turned on, the first node Na is at logic high, and then the third transistor P1 is turned off.

If the second input signal goes high, the second input transistor N1 is turned on, the second output terminal ODA2 is at logic low, and then the second node Nb is at logic high. Since the second node Nb is at logic high, the first transistor N2 is turned on and then the first output terminal ODA1 is at logic high.

Even if the second input signal transitions from logic low to logic high, the second node Nb is temporarily maintained at logic low, due to a delay in the inverter 422 of the output circuit 420. That is, since the second node Nb is temporarily maintained at logic low, the fourth transistor P2 is temporarily kept turned on and then is turned off. While the fourth transistor P2 is turned on, the second output terminal ODA2 is charged with electric charges from the supply voltage VDD2.

In order to allow the level shifter 400 to perform high-speed level shifting, the electric charges must be rapidly discharged from the second output terminal ODA2 to the ground voltage VSS via the second input transistor N1. That is, current contention occurs between the fourth transistor P2 and the second input transistor N1. Since the fourth transistor P2 is a pull-up transistor and thus smaller than the second input transistor N1, the second input transistor N1 has an advantage over the fourth transistor P2 in current contention.

Thus, the level shifter 400 can perform high-speed level shifting also while the first input signal transitions from logic high to logic low and the second input signal transitions from logic low to logic high.

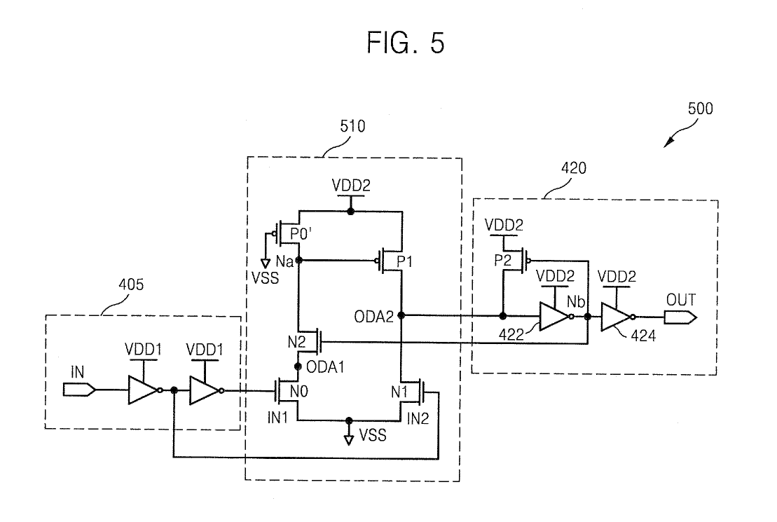

FIG. 5 is a circuit diagram of a level shifter 500 according to another embodiment of the present invention. Referring to FIG. 5, the level shifter 500 includes an input circuit 405, a differential amplification circuit 510, and an output circuit 420. The reference numerals that are the same as those of the level shifter 400 illustrated in FIG. 4 denote the same elements, and a description of their operations or characteristics will be omitted in this disclosure.

The gate of the second transistor P0 illustrated in FIG. 4 is connected to the first input terminal IN1 of the differential transistors N0 and N1, but the gate of a second transistor P0′ illustrated in FIG. 5 is connected to a ground voltage VSS. Accordingly, the second transistor P0′ is always kept turned on.

The operation of the level shifter 500 when a first input signal that goes low is supplied to a first input terminal IN1 and a second input signal that goes high is supplied to a second input terminal IN2 will now be described.

A first output terminal ODA1 is at logic high and a second output terminal ODA2 is at logic low. In this case, a first input transistor N0, a third transistor P1, and a fourth transistor P2 are turned off, and therefore, static current is not generated.

Next, the operation of the level shifter 500 when the first input signal transitions from logic low to logic high and the second input signal transitions from logic high to logic low will be described.

In order to allow the level shifter 500 to perform high-speed level shifting, electric charges charged to a first node Na by the second transistor P0′ must be rapidly discharged to the ground voltage VSS by the first input transistor N0.

That is, current contention occurs between the second transistor P0′ and the first input transistor N0. Since the second transistor P0′ is a pull-up transistor and thus smaller than the first input transistor N0, the first input transistor N0 has an advantage over the second transistor P0′ in current contention.

Accordingly, the level shifter 500 can perform high-speed level shifting while the first input signal transitions from logic low to logic high and the second input signal transitions from logic high to logic low.

When the first input signal is maintained at logic high and the second input signal is maintained at logic low, a first transistor N2, the third transistor P1, and the second input transistor N1 are turned off, and therefore, static current is not generated.

Next, the operation of the level shifter 500 when the first input signal transitions from logic high to logic low and the second input signal transitions from logic low to logic high will be described.

In order to allow the level shifter 500 to perform high-speed level shifting, electric charges charged to the second output terminal ODA2 by the fourth transistor P2 must be rapidly discharged to the ground voltage VSS via the second input transistor N1. That is, current contention occurs between the fourth transistor P2 and the second input transistor N1. Since the fourth transistor P2 is a pull-up transistor and thus smaller than the second input transistor N1, the second input transistor N1 has an advantage over the fourth transistor P2 in current contention.

Therefore, the level shifter 500 can perform high-speed level shifting while the first input signal transitions from logic high to logic low and the second input signal transitions from logic low to logic high.

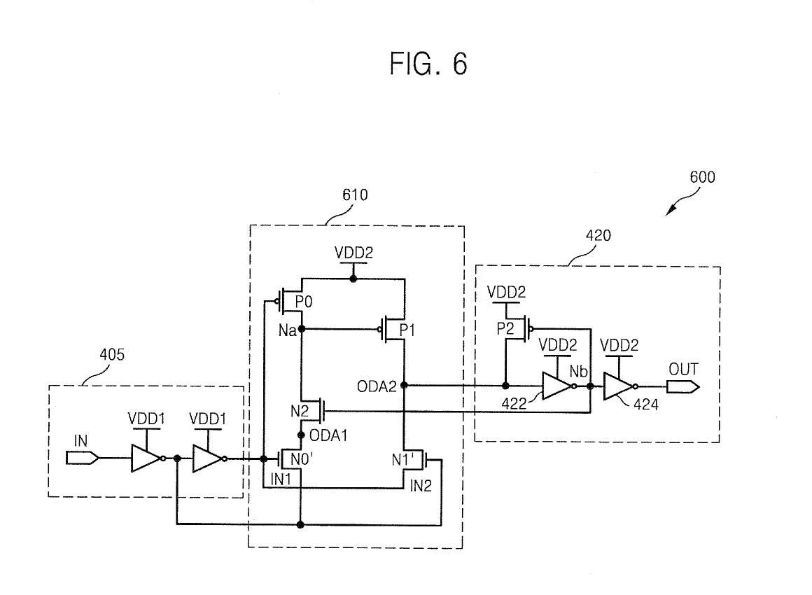

FIG. 6 is a circuit diagram of a level shifter 600 according to another embodiment of the present invention. Referring to FIG. 6, the level shifter 600 includes an input circuit 405, a differential amplification circuit 610, and an output circuit 420. The reference numerals that are the same as those of the level shifter 400 illustrated in FIG. 4 denote the same elements, and a description of their operations or characteristics will be omitted in this disclosure. Only the differences between the level shifter 600 and the level shifter 400 will be described here.

In the level shifter 400, the first input transistor N0 and the second input transistor N1 have a predetermined threshold voltage, e.g., 0.6 V, and the tails of the differential transistors N0 and N1 are connected to the ground voltage VSS.

However, in the level shifter 600, a first input transistor N0′ and a second input transistor N1′ have a zero threshold voltage. The source of the first input transistor N0′ is connected to a second input terminal IN2 and the source of the second input transistor N1′ is connected to a first input terminal IN1.

Since the first input transistor N0′ and the second input transistor N1′ have zero threshold voltage, if the tails of the differential transistors N0′ and N1′ are connected to the ground voltage VSS, the first input transistor N0′ or the second input transistor N1′ can be turned on even if the first input signal or the second input signal is low.

However, in the case of the level shifter 600, if the first input signal goes low, the source of the first input transistor N0′ is connected to the second input terminal IN2 to which a second input signal that goes high is supplied, and therefore, the first input transistor N0′ is not turned on.

Also, if the second input signal goes low, the source of the second input transistor N1′ is connected to the first input terminal IN1 to which the second input signal that goes high is supplied, and therefore, the second input transistor N1′ is not turned on.

However, when the first or second input signal goes high, the source of the first input transistor N0′ or the second input transistor N1′ is connected to an input terminal to which an input signal that goes low is supplied, and therefore, the first input transistor N0′ or the second input transistor N1′ is turned on.

The operation of the level shifter 600 is similar to that of the level shifter 400, except that the level shifter 600 can operate stably at 1 V or less since it includes the input transistors N0′ and N1 that have a zero threshold voltage.

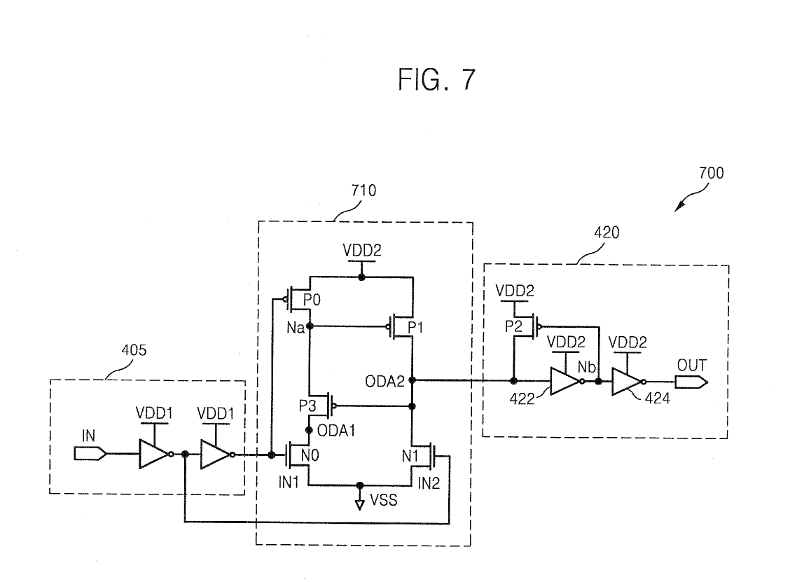

FIG. 7 is a circuit diagram of a level shifter 700 according to another embodiment of the present invention. Referring to FIG. 7, the level shifter 700 includes an input circuit 405, a differential amplification circuit 710, and an output circuit 420. The reference numerals that are the same as those of the level shifter 400 illustrated in FIG. 4 denote the same elements, and a description of their operations or characteristics will be omitted in this disclosure.

The first transistor N2 illustrated in FIG. 4 is an N-channel MOSFET whose gate is connected to the second node Nb, but a first transistor P3 illustrated in FIG. 7 is a P-channel MOSFET whose gate is connected to a second output terminal ODA2.

First, the operation of the level shifter 700 when a first input signal that goes low is supplied to a first input terminal IN1 and a second input signal that goes high is supplied to a second input terminal IN2 will be described.

A first output terminal ODA1 is at logic high and the second output terminal ODA2 is at logic low. In this case, a first input transistor N0, a third transistor P1, and a fourth transistor P2 of the differential amplification circuit 710 are turned off, an therefore, static current is not generated.

Next, the operation of the level shifter 700 when the first input signal transitions from logic low to logic high and the second input signal transitions from logic high to logic low will be described.

In order to allow the level shifter 700 to perform high-speed level shifting, electric charges charged to a first node Na via a second transistor P0 must be rapidly discharged to a ground voltage VSS via the first input transistor N0. That is, current contention occurs between the second transistor P0 and the first input transistor N0. The second transistor P0, which is a pull-up transistor, is smaller than the first input transistor N0 and has the same gate voltage as the first input transistor N0. Therefore, the first input transistor N0 has an advantage over the second transistor P0 in current contention.

Accordingly, the level shifter 700 can perform high-speed level shifting while the first input signal transitions from logic low to logic high and the second input signal transitions from logic high to logic low.

When the first input signal is maintained at logic high and the second input signal is maintained at logic low, the first transistor P3, the third transistor P1, and the second input transistor N1 are turned off, an thus, static current is not generated.

Next, the operation of the level shifter 700 when the first input signal transitions from logic high to logic low and the second input signal transitions from logic low to logic high will be described.

In order to allow the level shifter 700 to perform high-speed level shifting, electric charges charged to the second output terminal ODA2 via the fourth transistor P2 must be rapidly discharged to the ground voltage VSS via the second input transistor N1. That is, current contention occurs between the fourth transistor P2 and the second input transistor N1. Since the fourth transistor P2 is a pull-up transistor and thus smaller than the second input transistor N1, the second input transistor N1 has an advantage over the fourth transistor P2 in current contention.

Accordingly, the level shifter 700 can perform high-speed level shifting while the first input signal transitions from logic high to logic low and the second input signal transitions from logic low to logic high.

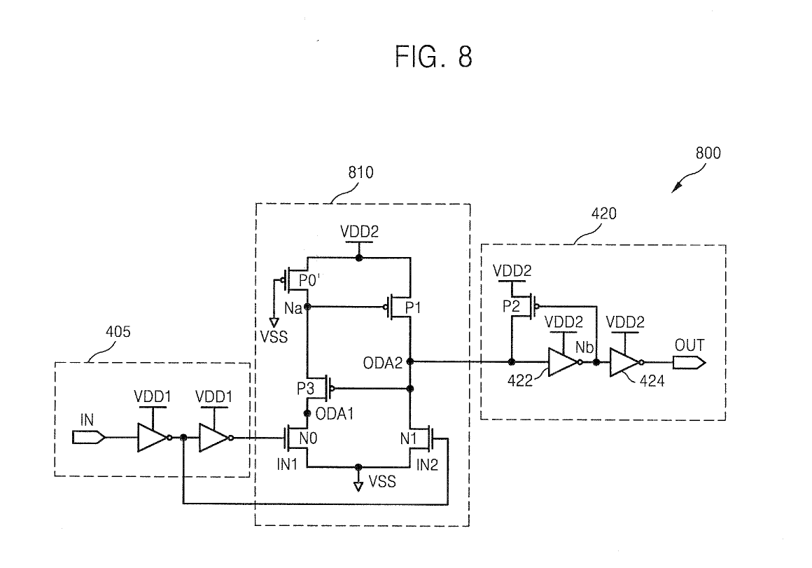

FIG. 8 is a circuit diagram of a level shifter 800 according to another embodiment of the present invention. Referring to FIG. 8, the level shifter 800 includes an input circuit 405, a differential amplification circuit 810, and an output circuit 420. The reference numerals that are the same as those of the level shifter 400 illustrated in FIG. 4 denote the same elements, and a description of their operations or characteristics will be omitted in this disclosure.

The gate of the second transistor P0 illustrated in FIG. 4 is connected to the first input terminal IN1 of the differential transistors N0 and N1, but the gate of a second transistor P0′ illustrated in FIG. 8 is connected to a ground voltage VSS. Accordingly, the second transistor P0′ is always kept turned on.

The first transistor N2 illustrated in FIG. 4 is an N channel MOSFET whose gate is connected to the second node Nb, but a first transistor P3 illustrated in FIG. 8 is a P channel MOSFET whose gate is connected to a second output terminal ODA2.

The operation of the level shifter 800 when a first input signal that goes low is supplied to a first input terminal IN1 and a second input signal that goes high is supplied to a second input terminal IN2 will now be described.

A first output terminal ODA1 is at logic high and the second output terminal ODA2 is at logic low. In this case, a first input transistor N0, a third transistor P1, and a fourth transistor P2 are turned off, and therefore, static current is not generated.

Next, the operation of the level shifter 800 when the first input signal transitions from logic low to logic high and the second input signal transitions from logic high to logic low will be described.

In order to allow the level shifter 800 to perform high-speed level shifting, electric charges charged to the first node Na via the second transistor P0′ must be rapidly discharged to a ground voltage VSS via the first input transistor N0. That is, current contention occurs between the second transistor P0′ and the first input transistor N0. Since the second transistor P0′ is a pull-up transistor and thus smaller than the first input transistor N0, the first input transistor N0 has an advantage over the second transistor P0′ in current contention.

Accordingly, the level shifter 800 can perform high-speed level shifting while the first input signal transitions from logic low to logic high and the second input signal transitions from logic high to logic low.

When the first input signal is maintained at logic high and the second input signal is maintained at logic low, the first transistor P3, the third transistor P1, and the second input transistor N1 are turned off, and therefore, static current is not generated.

Next, the operation of the level shifter 800 when the first input signal transitions from logic high to logic low and the second input signal transitions from logic low to logic high will be described.

In order to allow the level shifter 800 to perform high-speed level shifting, electric charges charged to the second output terminal ODA2 via the fourth transistor P2 must be rapidly discharged to the ground voltage VSS via the second input transistor N1. That is, current contention occurs between the fourth transistor P2 and the second input transistor N1. Since the fourth transistor P2 is a pull-up transistor and thus smaller than the second input transistor N1, the second input transistor N1 has an advantage over the fourth transistor P2 in current contention.

Therefore, the level shifter 800 can perform high-speed level shifting while the first input signal transitions from logic high to logic low and the second input signal transitions from logic low to logic high.

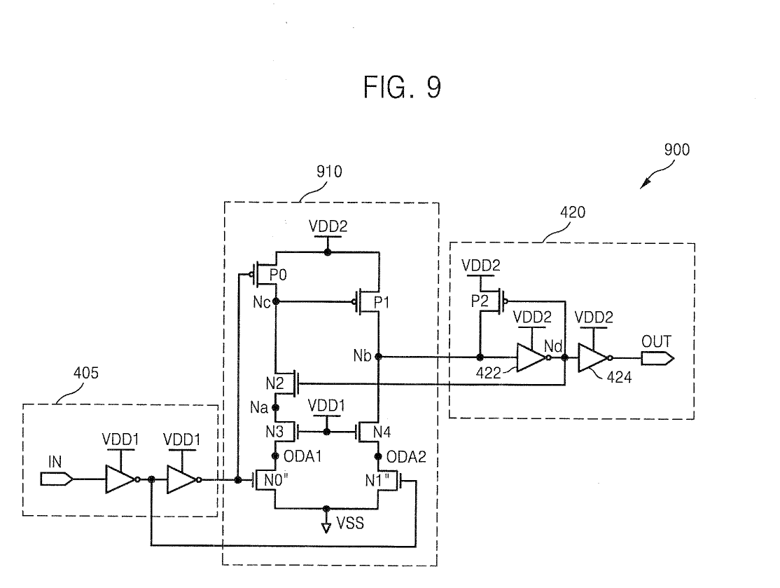

FIG. 9 is a circuit diagram of a level shifter 900 according to another embodiment of the present invention. Referring to FIG. 9, the level shifter 900 includes an input circuit 405, a differential amplification circuit 910, and an output circuit 420. The reference numerals that are the same as those of the level shifter 400 illustrated in FIG. 4 denote the same elements, and a description of their operations or characteristics will be omitted in this disclosure. The operation of the level shifter 900 is the same as that of the level shifter 400, and thus, only structural differences between the level shifter 900 and the level shifter 400 will be described here.

The break-down voltage of the gate layer of each of the input transistors N0 and N1 of the level shifter 400 is equal to a second supply voltage VDD2, but the break-down voltage of the gate layer of each of input transistors N0″ and N1″ of the level shifter 900 is equal to a first supply voltage VDD1. That is, the gate layer of each of the input transistors N0″ and N1″ of the level shifter 900 is thinner than the gate layer of the input transistors N0 and N1 of the level shifter 400.

This means that the threshold voltage of each of the input transistors N0″ and N1″ is lower than the threshold voltage of each of the input transistors N0 and N1. Thus, the level shifter 900 can operate stably at a low input voltage, e.g., 1 V or less.

Also, the level shifter 900 further includes a fifth transistor N3 connected between a first transistor N2 and a first output terminal ODA1, and a sixth transistor N4 connected between a third transistor P1 and a second output terminal ODA2. Both the gates of transistors N3 and N4 are connected to a first supply voltage VDD1.

Since the transistors N3 and N4 have a zero threshold voltage, it is possible to prevent a second supply voltage from being applied directly to the differential transistors N0″ and N1″ of the level shifter 900. Accordingly, the transistors N3 and N4 protect the differential transistors N0″ and N1″.

As described above, a level shifter according to the present invention is capable of preventing generation of static current and performing high-speed shifting at low driving voltage.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A level shifter comprising:
a pair of differential transistors of a first conductive type having a first input terminal and a second input terminal;
a first transistor of the first conductive type which is connected between a first node and a first output terminal of the differential transistors and a gate of which is connected to a second node;
a second transistor of a second conductive type connected between a supply voltage and the first node; and
a third transistor of the second conductive type which is connected between the supply voltage and a second output terminal of the differential transistors and a gate of which is connected to the first node.

2. The level shifter of claim 1, further comprising:
an inverter connected between the second output terminal of the differential transistors and the second node; and
a fourth transistor of the second conductive type which is connected between the supply voltage and the second output terminal of the differential transistors and a gate of which is connected to the second node.

3. The level shifter of claim 2, wherein the second transistor has a gate connected to the first input terminal.

4. The level shifter of claim 2, wherein the second transistor has a gate connected to a ground voltage.

5. The level shifter of claim 2, wherein a first input transistor and a second input transistor which are the differential transistors have a zero threshold voltage.

6. The level shifter of claim 5, wherein a source of the first input transistor is connected to the second input terminal, and a source of the second input transistor is connected to the first input terminal.

7. A level shifter comprising:
a pair of differential transistors of a first conductive type having a first input terminal and a second input terminal;
a first transistor of a second conductive type which is connected between a first node and a first output terminal of the differential transistors and a gate of which is connected to a second output terminal of the differential transistors;
a second transistor of the second conductive type connected between a supply voltage and the first node; and
a third transistor of the second conductive type which is connected between the supply voltage and the second output terminal of the differential transistors and a gate of which is connected to the first node.

8. The level shifter of claim 7, further comprising:
an inverter connected between the second output terminal of the differential transistors and a second node; and
a fourth transistor of the second conductive type which is connected between the supply voltage and the second output terminal of the differential transistors and a gate of which is connected to the second node.

9. The level shifter of claim 8, wherein the second transistor has a gate connected to the first input terminal.

10. The level shifter of claim 8, wherein the second transistor has a gate connected to a ground voltage.

11. A level shifter comprising:
a pair of differential transistors of a first conductive type having a first input terminal and a second input terminal;
a pair of first transistors of the first conductive type, where a first one of the first transistors is connected between a first node and a first output terminal of the differential transistors, a second one of the first transistors is connected between a second node and a second output terminal of the differential transistors and each of the first transistors has a gate connected to a first supply voltage;
a second transistor of the first conductive type which is connected between a third node and the first node and a gate of which is connected to a fourth node;
a third transistor of a second conductive type connected between a second supply voltage and the third node; and
a fourth transistor of the second conductive type which is connected between the second supply voltage and the second node and a gate of which is connected to the third node.

12. The level shifter of claim 11, wherein the second supply voltage is obtained by level shifting the first supply voltage.

13. The level shifter of claim 11, wherein a gate layer of each of the first transistors has a break-down voltage equal to the second supply voltage, and a zero threshold voltage.

14. The level shifter of claim 11, further comprising:
an inverter connected between the second node and the fourth node; and
a fifth transistor of the second conductive type which is connected between the second supply voltage and the second node and a gate of which is connected to the fourth node.

15. The level shifter of claim 14, wherein the third transistor has a gate connected to the first input terminal of the pair of differential transistors.

16. The level shifter of claim 1, wherein each of the transistors of the first conductive type is an N channel MOSFET (metallic oxide semiconductor field effect transistor), and each of the transistors of the second conductive type is a P channel MOSFET.

17. The level shifter of claim 2, wherein the second and fourth transistors are substantially smaller than the differential transistors.

18. The level shifter of claim 7, wherein each of the transistors of the first conductive type is an N channel MOSFET (metallic oxide semiconductor field effect transistor), and each of the transistors of the second conductive type is a P channel MOSFET.

19. The level shifter of claim 8, wherein the second transistor and the fourth transistors are substantially smaller than the differential transistors.

20. The level shifter of claim 11, wherein each of the transistors of the first conductive type is an N channel MOSFET (metallic oxide semiconductor field effect transistor), and each of the transistors of the second conductive type is a P channel MOSFET.
